(19) United States
(12) Patent Application Publication
(10) Pub. No.: US 2014/0339490 A1
(43) Pub. Date: Nov. 20, 2014

(54) RESISTIVE SWITCHING MEMORY DEVICE HAVING IMPROVED NONLINEARITY AND METHOD OF FABRICATING THE SAME

(71) Applicant: Industry-Academic Cooperation Foundation, Yonsei University, Seoul (KR)

(72) Inventors: Hyun Chul SOHN, Seoul (KR); Dae Hong Ko, Goyang si (KR); Jong Gi Kim, Seoul (KR); Jin Ho Oh, Seoul (KR); Young Jae Kim, Seoul (KR)

(73) Assignee: Industry-Academic Cooperation Foundation, Yonsei University, Seoul (KR)

(21) Appl. No.: 14/275,928

(22) Filed: May 13, 2014

(30) Foreign Application Priority Data
May 14, 2013 (KR) 10-2013-0054287

(51) Int. Cl. H01L 45/00

(52) U.S. Cl. CPC H01L 45/145; H01L 45/1608
USPC 257/2; 438/382

(57) ABSTRACT

A nonvolatile resistive switching memory (ReRAM) device having no selection device is provided. The ReRAM device includes a lower electrode that is formed on on a substrate; a metal oxide layer that is formed on the lower electrode, the metal oxide layer having a resistive switching characteristic; an upper electrode that is formed on the metal oxide layer; and a tunnel barrier oxide film that is formed between the lower electrode and the metal oxide layer, thereby forming a double oxide film structure, the tunnel barrier oxide film being made of a material, a band energy gap and a conduction band offset of which are lower than those of the metal oxide layer, and which does not cause interface switching.

### CROSS REFERENCE TO RELATED APPLICATION

The present application claims priority from Korean Patent Application Number 10-2013-0054287 filed on May 14, 2013, the entire contents of which are incorporated herein for all purposes by this reference.

### BACKGROUND OF THE INVENTION

1. Field of the Invention

The present invention relates to a resistive switching memory device, and more particularly, to a resistive switching memory device having improved nonlinearity characteristic and a method of fabricating the same.

2. Description of Related Art

The semiconductor industry has developed successfully up to the present based on miniaturization and integration in the 1980s and ultra-miniaturization and high-integration in the 1990s. These successes are based on the device operating principle that can remain unchanged even if the size of the device is reduced. Therefore, all research and development have been made on an extension from the traditional technologies, and the results have been successful until now.

However, in response to the accelerating development of telecommunications, there is increasing necessity for improvements in the performance of semiconductor devices and systems that can more rapidly process increasing amounts of information. For this purpose, ultra-high speed, ultra-high integration and ultra-high power saving are required for a memory device, which is an essential component. Therefore, the necessity for development of a nonvolatile memory device capable of ultra-high integration necessary for storing large amounts of information is becoming greater than ever.

Recently, according to the international technology roadmap for semiconductors (ITRS), devices that are regarded as strong candidates for next-generation nonvolatile memory devices include phase change random-access memory (PRAM), nano floating gate memory (NFGM), resistive random-access memory (ReRAM), polymer random-access memory (PoRAM), magnetic random-access memory (MRAM), molecular memory and the like. The development of the next-generation memory is intended to realize all of the high integration and low power consumption of DRAM, the nonvolatility of flash memory and high-speed operation of SRAM. In particular, ReRAM devices are regarded as leading next-generation memory devices since they have all the advantages of memory devices.

A conventional nonvolatile resistive switching memory has an operating process as follows: The nonvolatile resistive switching memory undergoes a forming process in which a high resistance state (HRS), which is intrinsic to a metal oxide film, is converted into a low resistance state (LRS) by an applied voltage. Afterwards, the nonvolatile resistive switching memory undergoes, in response to applied voltages, a reset process in which the LRS is converted into the HRS and a set process in which the HRS is converted into the LRS. In this manner, a nonvolatile resistive switching memory performs a resistance switching operation. In general, for the fabrication of a cross-point ReRAM device, the role of a selection device is important since the selection device blocks a sneak current generated from a cell other than a selected cell when the cross-point ReRAM device operates.

Specifically, the development of cross-bar cell arrays is being carried out in order to realize an ideal high-integrated memory device. However, interference is caused by a sneak current between neighboring cells due to the unique characteristics of the cross-bar cell array, and an error occurs in a data reading operation or the like.

In relation to this, each cell is provided with a selection device which allows the cell to be selected and read (see, for example, Korean Patent Application Publication No. 10-2012-59195). The selection device is implemented as a transistor or a diode. The selection device has I-V characteristics which are symmetric with respect to positive (+) and negative (−) external electric fields, unlike a diode. A superior nonlinearity characteristic, in which a low current flows at a low external electric field and a high current flows at a high external electric field, is required. However, this method of the related art has the following problems: The structure is complicated since each selection device is provided; and the nonlinearity characteristic is not properly realized. In addition, the ReRAM having a single oxide film structure is difficult to operate in the ON state nonlinearity characteristic as required in order to realize the high integrity required in the semiconductor industry.

The information disclosed in the Background of the Invention section is provided only for enhancement of (or better) understanding of the background of the invention, and should not be taken as an acknowledgment or any form of suggestion that this information forms a prior art that would already be known to a person skilled in the art.

### BRIEF SUMMARY OF THE INVENTION

Various aspects of the present invention provide a resistive switching memory device having improved nonlinearity characteristic and a method of fabricating the same.

Also provided is a resistive switching memory device and a method of fabricating the same, in which a sneak current can be efficiently reduced in the reading/writing step without a selection device through improved nonlinearity.

In an aspect of the present invention, provided is a nonvolatile resistive switching memory (ReRAM) device having no selection device, which ReRAM device includes:

a lower electrode that is formed on on a substrate;

a metal oxide layer that is formed on the lower electrode, the metal oxide layer having a resistive switching characteristic;

an upper electrode that is formed on the metal oxide layer; and

a tunnel barrier oxide film that is formed between the lower electrode and the metal oxide layer, thereby forming a double oxide film structure. The tunnel barrier oxide film is made of a material, a band energy gap and a conduction band offset of which are lower than those of the metal oxide layer, and which does not cause interface switching.

According to an embodiment of the present invention, the tunnel barrier oxide film may be formed from a material, the crystallization temperature of which is 500° C. or higher.

According to an embodiment of the present invention, the tunnel barrier oxide film may be made of one selected from a group consisting of Ta₂O₅, Nb₂O₅, BaTiO₃ and BaZrO₃.

According to an embodiment of the present invention, the metal oxide layer may be made of one selected from a group consisting of ZrO₂, HfO₂, SiO₂, Al₂O₃, ZrAlOx, HfAlOx, HfSiOx or La₂O.

According to an embodiment of the present invention, the resistive switching memory (ReRAM) device may be applied to a cross-point ReRAM device structure, thereby reducing a sneak current.

In an aspect of the present invention, provided is a method of fabricating a resistive switching memory (ReRAM) device having no selection device. The method includes the following steps of:

forming a lower electrode on a substrate;

forming a metal oxide layer having a resistive switching characteristic on the lower electrode;

forming an upper electrode on the metal oxide layer; and

forming a tunnel barrier oxide film between the lower electrode and the metal oxide layer, thereby forming a double oxide film structure. The tunnel barrier oxide film is made of a material, a band energy gap and a conduction band offset of which are lower than those of the metal oxide layer, and which does not cause interface switching.

According to an embodiment of the present invention, the tunnel barrier oxide film may be formed from a material, the crystallization temperature of which is 500° C. or higher.

According to an embodiment of the present invention, the tunnel barrier oxide film may be made of one selected from a group consisting of Ta₂O₅, Nb₂O₅, BaTiO₃ and BaZrO₃.

According to an embodiment of the present invention, the metal oxide layer may be made of one selected from a group consisting of ZrO₂, HfO₂, SiO₂, Al₂O₃, ZrAlOx, HfAlOx, HfSiOx or La₂O.

As set forth above, when the interfacial nonlinearity resistive switching memory device based on tunnel barrier engineering is developed by the method of the present invention from among a variety of methods of fabricating a nonvolatile resistive switching memory, it is possible to improve the on-state nonlinearity characteristic and develop a high-performance, high-integrated and reliable resistive switching memory device. It is possible to easily fabricate a cross-point ReRAM device having a 1R-structure that prevents a leakage current from being formed by a half voltage in an unselected cell portion to which the half voltage is to be induced, without application of a diode. Based on these advantages, it is possible to realize a memory device having low-power and high-performance characteristics, which are required for next-generation memory devices.

The methods and apparatuses of the present invention have other features and advantages which will be apparent from, or are set forth in greater detail in the accompanying drawings, which are incorporated herein, and in the following Detailed Description of the Invention, which together serve to explain certain principles of the present invention.

### BRIEF DESCRIPTION OF THE DRAWINGS

FIG. 1 is a view showing the configuration and the nonlinearity characteristic of a cross-point ReRAM device, as well as the importance of a Kw value in the cross-point ReRAM device;

FIG. 2 is a view showing the literature values of the band gap and conduction band offset of an oxide film, as well as the crystallization temperature of Ta₂O₅ (Referring to XRD data, a peak appears at 800° C. This indicates that 800° C. is the crystallization temperature);

FIG. 3 is a view showing the nonlinearity resistive switching characteristic, the Kw value and the on/off ratio characteristic of a HfO₂ single oxide film depending on the compliance current;

FIG. 4 is a view showing the nonlinearity resistive switching characteristic, the Kw value and the on/off ratio characteristic of a double oxide film structure including a HfO₂ switching thin film and an Al₂O₃ tunnel barrier thin film depending on the compliance current;

FIG. 5 is a view showing the reason why the on-state nonlinearity characteristic at a set step is improved when a tunnel barrier oxide film, of which the conduction band offset and band gap are low, is used;

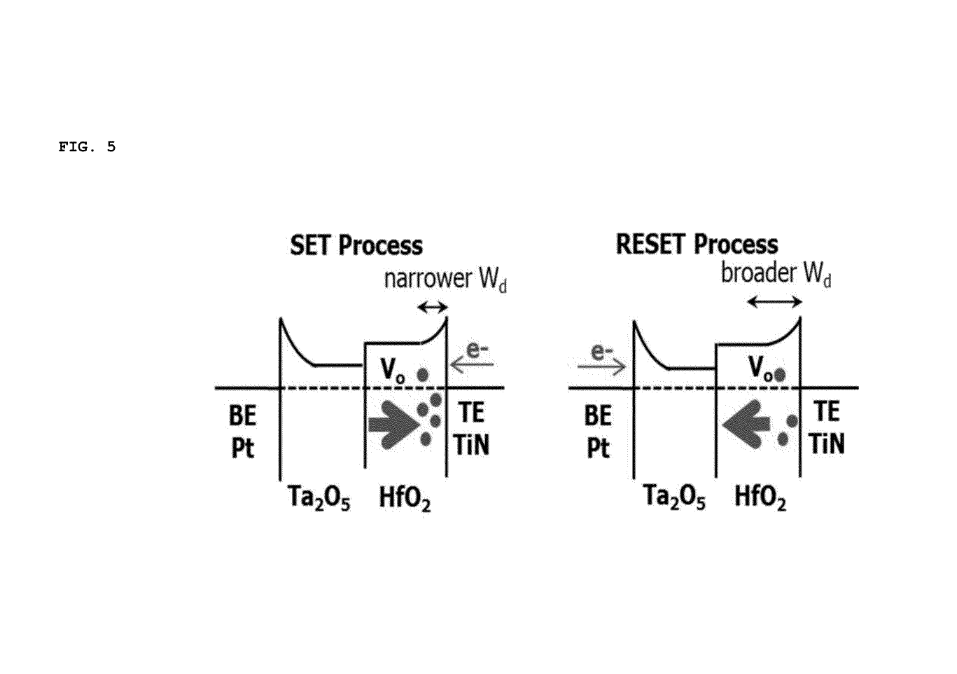

FIG. 6 is a view showing the nonlinearity resistive switching characteristic and switching model of TiN/HfO₂/TiO₂/Pt and TiN/TiO₂/HfO₂/Pt; and

FIG. 7 is a view showing that the on-state nonlinearity characteristic of an Al₂O₃ tunnel barrier is further improved in response to a Kw value with respect to an on/off ratio and a driving current being improved when a Ta₂O₅ tunnel barrier oxide film, of which the conduction band offset and band gap are low, is used.

### DETAILED DESCRIPTION OF THE INVENTION

Reference will now be made in detail to exemplary embodiments of the present invention in conjunction with the accompanying drawings. Herein, detailed descriptions of some technical constructions or terms well known in the art will be omitted. In particular, descriptions of known elements involving a memory device, such as the function and configuration of each layer of a resistive switching memory device (ReRAM) device will be omitted. Even if such descriptions are omitted, the features of the present invention will be apparent to a person skilled in the art from the following description.

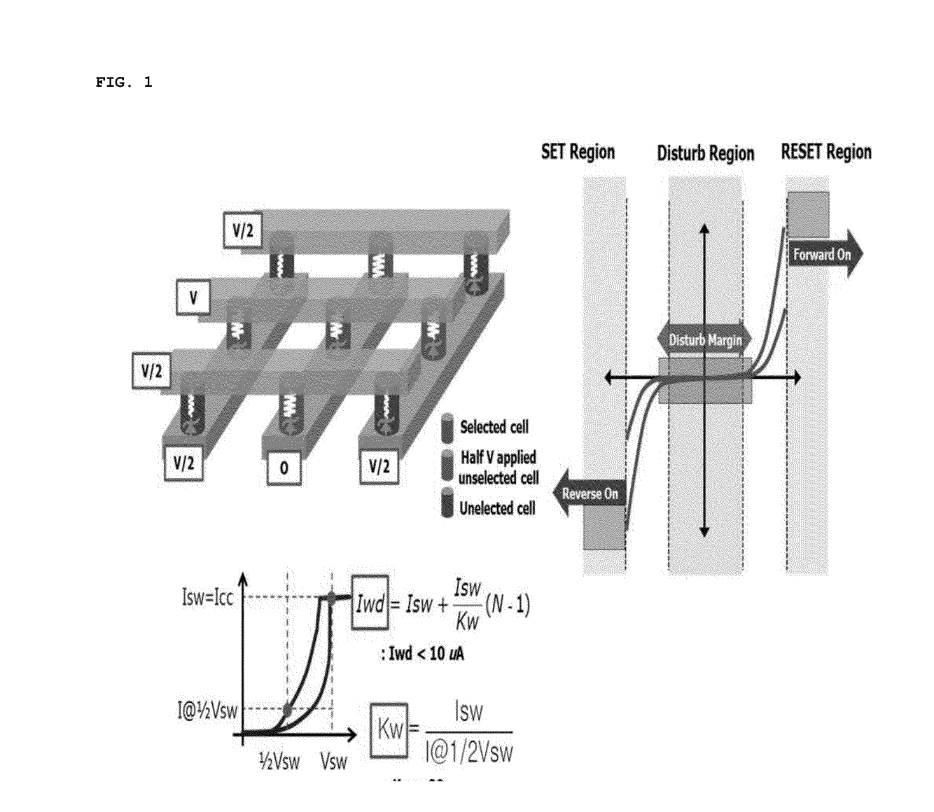

FIG. 1 a view showing the configuration and the nonlinearity characteristic of a cross-point ReRAM device, as well as the importance of a Kw value in the cross-point ReRAM device. Specifically, the Kw value indicates a ratio of an on-state current applied to the half of a writing voltage with respect to a current that flows when the writing voltage is applied. The cross-point structure shown in FIG. 1 indicates that the half of the applied voltage is applied around a selected device. Here, it is possible to increase the size of one block at a high Kw value in order to increase integrity.

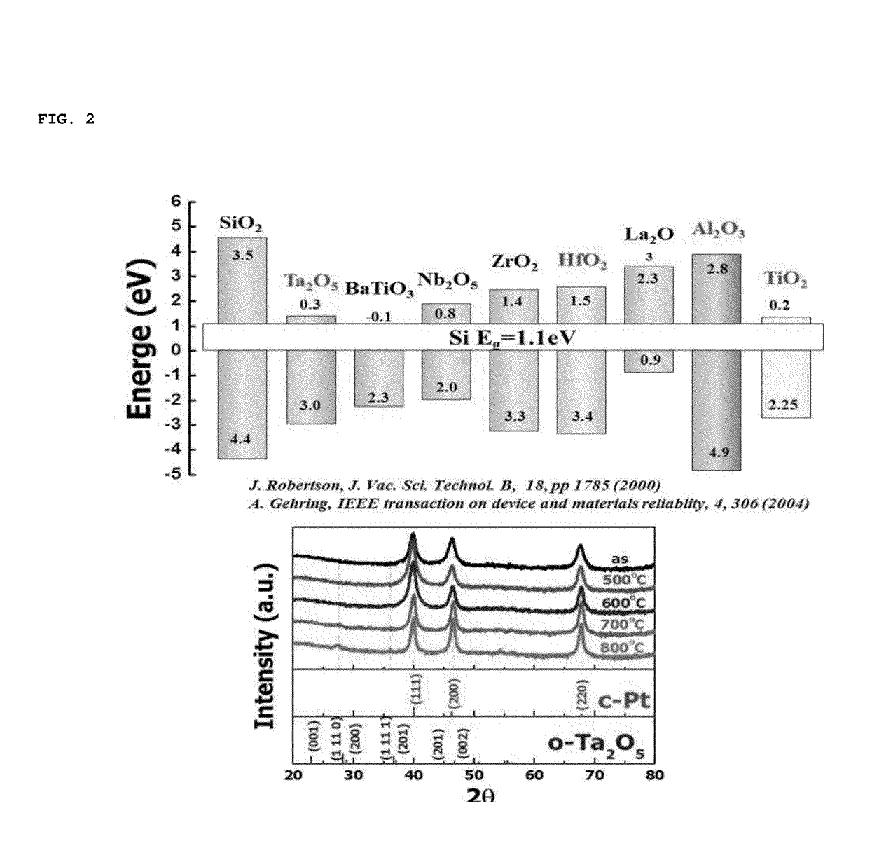

FIG. 2 is a view showing the literature values of the band gap and conduction band offset of an oxide film, as well as the crystallization temperature of Ta₂O₅. According to the present invention, a metal oxide layer having a variable oxide thickness (VARIOT) structure (a double film structure) is formed from a material, the band gap energy and conduction band offset of which are relatively lower than those of a metal oxide layer that has a resistive switching characteristic. The present invention will now be described in greater detail.

An ReRAM device without a selection device according to an exemplary embodiment of the present invention is fabricated by the following steps of: forming a lower electrode on a substrate; forming a metal oxide layer having a resistive switching characteristic on the lower electrode; and forming an upper electrode on the metal oxide layer. Here, unlike a conventional ReRAM device, a tunnel barrier oxide film is formed between the lower electrode and the metal oxide layer, thereby forming a double oxide film structure. The tunnel barrier oxide film is made of a material, of which the band energy gap and the conduction band offset are lower than those of the metal oxide layer, and which does not cause interface switching. The metal oxide film for resistive switching is not formed as a single film but the tunnel barrier oxide film having the above-described characteristics is formed under the metal oxide film and over the lower electrode, thereby improving the nonlinearity characteristic in the on-state.

Describing in greater detail, a Schottky contact is formed at the interface between the electrode and the oxide film. A Schottky depletion region in the Schottky contact is varied depending on the number of oxygen holes. This consequently changes the amount of electrons that can flow, thereby changing the resistance state. Since the tunnel barrier effect can be maximized when such switching occurs only in a switching thin film without resistive switching, the present invention employs a material that does not cause interface switching. In the meantime, the nonlinearity characteristic is improved not only in the on-state but also in the off state. Since the nonlinearity characteristic in the off-state is sufficiently good, the nonlinearity characteristic in the on-state is important in an actual device. Accordingly, the present invention is intended to improve the nonlinearity characteristic in the on-state.

The known step of forming the lower electrode may include the following processes of: depositing a first conductive material which is to form the lower electrode on the substrate and depositing a first insulating film which is to separate electrode patterns from each other; patterning the first insulating film to form the lower electrode and then depositing and planarizing a second insulating film which separates the metal oxide film each other and the upper electrode and the lower electrode each other; and patterning contact holes to connect the upper electrode to the lower electrode via the metal oxide film (three-dimensional multilayer structure).

The lower electrode can be made of any one of metal substances that are generally used for metal lines in fabrication of semiconductor devices. In addition, the lower electrode can be made of Pt, Si or a Si metal oxide. Representative examples of the material for the lower electrode may include metal substances, such as Al, W, Cu, Pt, TiN, TaN, Ti, Ta and Pt; Si; and Si metal oxides, such as WSix, NiSix, CoSix and TiSix.

The step of forming the tunnel barrier oxide film is the process of depositing a material having the above-described characteristics on top of the patterned lower electrode. Specifically, the material used in this step has a low band gap and a low conduction band offset (typically proportional to the band gap energy), does not cause interface switching, and has a crystallization temperature of, preferably, 500° C. or higher. (Specifically, ReRAM is eventually stacked within the cross-point structure. When a process equipment for atomic layer deposition (ALD) or chemical vapor deposition (CVD) is used, the ReRAM is inevitably subjected to process heat of 400° C. or lower. Since the ReRAM is subjected to the process heat for an extended time during the formation of the stacked structure, the tunnel barrier oxide film is formed from a material, the crystallization temperature of which is sufficiently high, in particular, 500° C. or higher according to an exemplary embodiment of the present invention.) For example, the material can be one selected from among, but not limited to, Ta₂O₅, Nb₂O₅, BaTiO₃ and BaZrO₃.

The step of forming the metal oxide film for resistive switching is the process of depositing a metal oxide film on the tunnel barrier oxide film. The metal oxide film can be made of one selected from among, but not limited to, ZrO₂, HfO₂, SiO₂, Al₂O₃, ZrAlOx, HfAlOx, HfSiOx and La₂O, of which the band gap energy and the conduction band offset are higher than those of the tunnel barrier oxide film.

When the tunnel barrier oxide film is formed between the lower electrode and the metal oxide film for resistive switching, the tunnel barrier oxide film is made of a material, the band gap energy of which is lower than the band gap energy of the metal oxide film for resistive switching, in order to improve nonlinearity characteristic and reduce a leakage current as will be described later.

Here, the high band gap energy and the low band gap energy are of a relative concept. According to the present invention, comparing to a material (e.g. HfO₂, SiO₂, Al₂O₃ or ZrO₂) having a high level of band gap energy ranging approximately from 5.7 to 9.0 eV (e.g. about 5.72 eV, which is the band gap energy of HfO₂), a material (e.g. Ta₂O₅), the band gap energy of which is lower than the former and ranges approximately from 3.0 to 4.5 eV (e.g. about 4.4 eV, which is the band bap energy of Ta₂O₅), can be used for a lower band gap energy material.

The step of forming the upper electrode includes the process of depositing a conductive film which is used for an electrode material on the oxide film for resistive switching and then patterning the deposited conductive film. Like the lower electrode, the upper electrode can be made of a metal substance that is generally used for metal lines in fabrication of semiconductor devices. Typical examples of this metal material include Ti, Al, Ta, TaN and TiN. The material of the lower electrode and the material of the upper electrode may not be necessarily equal. The step of forming the upper electrode may also include depositing an additional insulation film on the upper electrode for the purpose of a short-circuit with the patterned upper electrode, followed by chemical/physical polishing.

### EXAMPLES

The inventors deposited different thicknesses of O₃ reactant-based Ta₂O₅ tunnel barrier oxide films on Pt electrode-based 250×250 nm² contact hole-type devices. Each of the tunnel barrier oxide films has a low band gap, a low conduction band offset and a crystallization temperature of 500° C. or higher, and does not cause interface switching. Afterwards, a H₂O reactant-based HfO₂ metal oxide film which serves for interface resistive switching was deposited, and TiN serving as the upper electrode was deposited on the metal oxide film. (In this manner, a TiN/HfO₂/Ta₂O₅/Pt device was fabricated.)

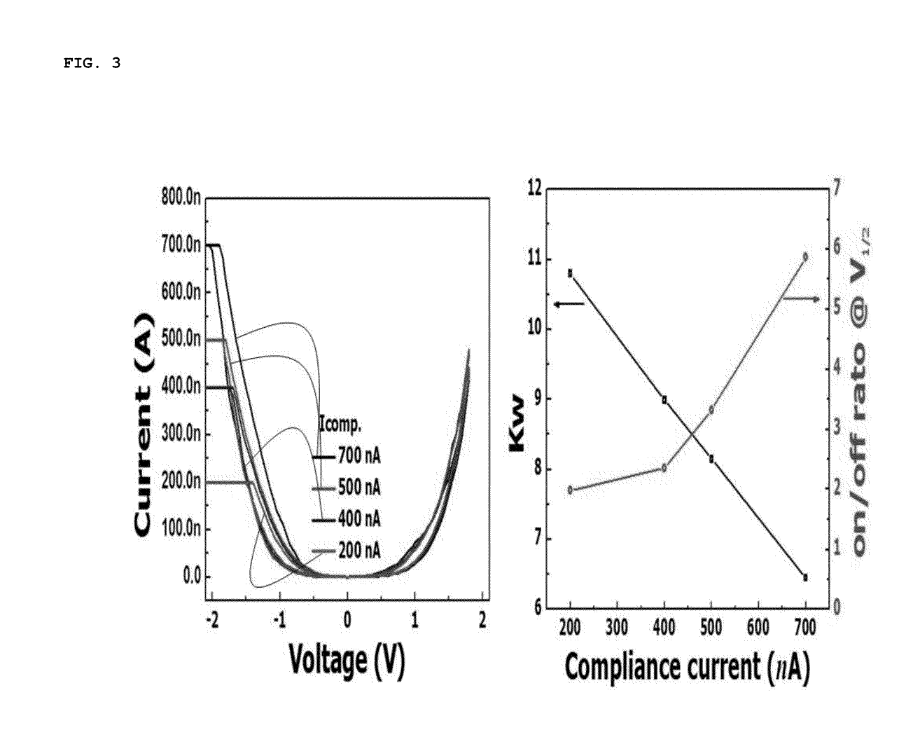

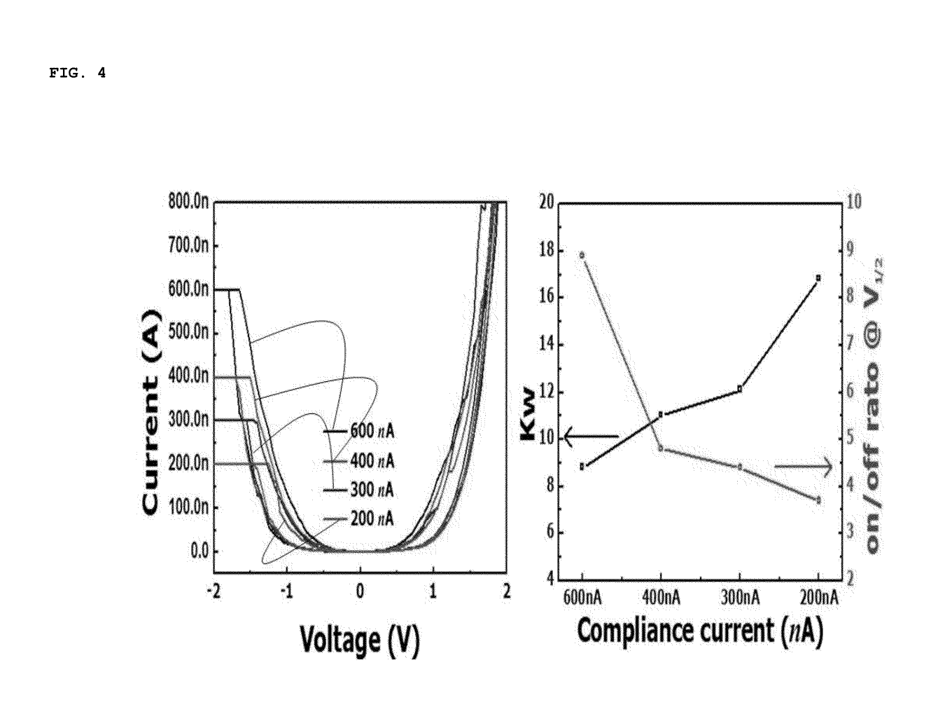

As a comparative example of the present invention, an ReRAM device was formed under the same conditions except for the tunnel barrier oxide film (i.e. a TiN/HfO₂/Pt device was fabricated). In this case, a forming process is enabled when a high voltage is applied under a positive (+) external bias, and a reset process is enabled under a negative (−) external bias. However, a nonlinear set process is enabled when a negative (−) external bias that does not enable the forming process is induced, and an interface resistive switching characteristic appears when a reset process is enabled at a positive (+) voltage lower than that of the forming process (see FIG. 3). According to the characteristics of the interface resistive switching, there is no forming process, it is not required to set a compliance current, and the thickness of a transition metal oxide film is adjusted such that switching occurs at a low current. In addition, as another comparative example, a TiN/HfO₂/Al₂O₃/Pt device was fabricated by applying a tunnel barrier oxide film having a high band gap and a high conduction band offset, unlike the present invention. The TiN/HfO₂/Al₂O₃/Pt device has an improvement in a Kw value, which shows a nonlinearity characteristic in the on-state. Describing in greater detail, the data show the nonlinearity characteristic when the tunnel barrier is made of a material having a high band gap energy. The data are to be compared with the following case in which a tunnel barrier is formed of a material having a low band gap energy. In this case, although Kw can be increased in a similar manner, a relative operating current is too low. When the relative operating current is raised high, the Kw value is significantly reduced, which is problematic. In the on-state, when a current is several nano-amperes or less at a read voltage, reading is impossible. A current must properly range from 300 nA to 1 μA in the reading state. However, the maximum current is several nano-amperes in the graph of FIG. 4, and application is impossible.

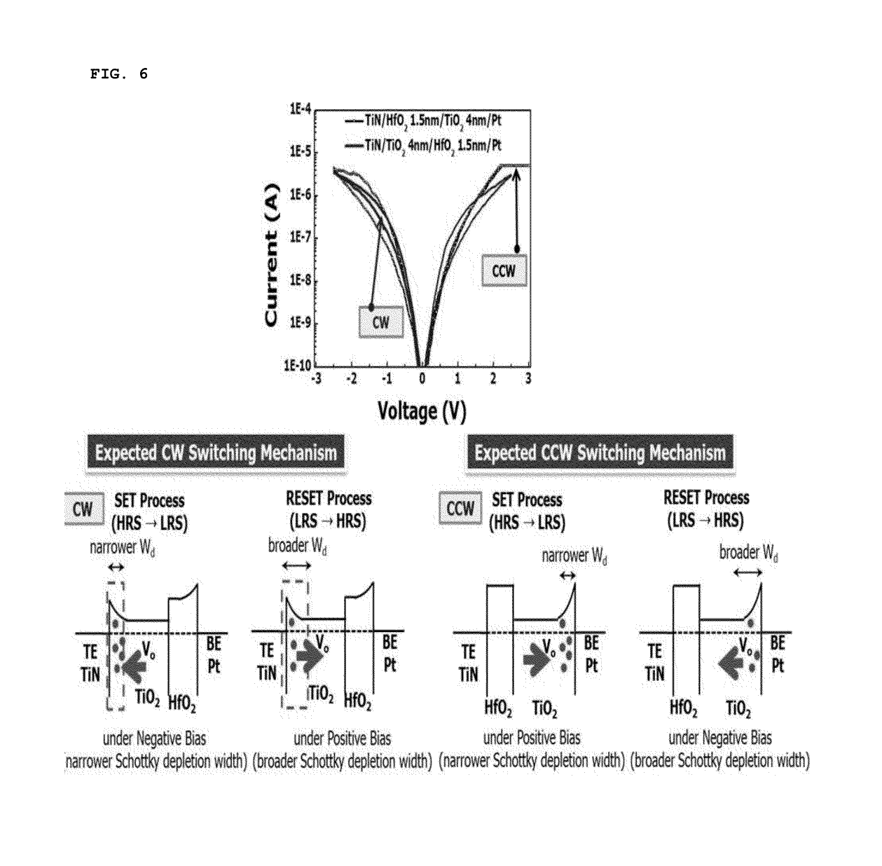

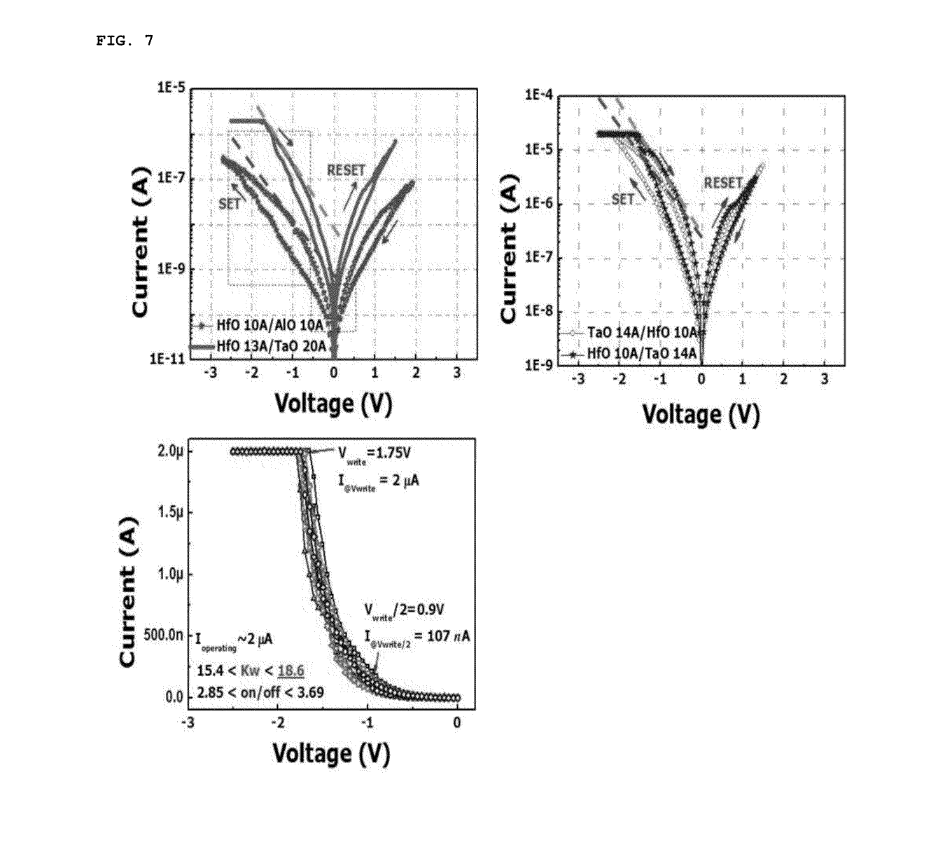

However, according to the present invention, the Kw value was the highest in the TiN/HfO₂/Ta₂O₅/Pt device (inventive example) to which the tunnel barrier oxide film, of which the band gap and conduction band offset are low, was applied. The operating current is easier to adjust than that of the Al₂O₃ metal oxide layer, of which the band gap and high conduction band offset are high. In addition, in the thin film made of, for example, TiO₂, the crystallization temperature of which is about 250° C., and in which interface resistive switching occurs at an interface with the Pt electrode, the TiO₂ thin film does not serve as the tunnel barrier but its switching direction changes between clockwise direction and counterclockwise direction depending on the position of TiO₂ (see FIG. 6). In contrast, it is confirmed that the switching direction of the Ta₂O₅ tunnel barrier does not change depending on the position. The overall on/off ratio is 4, and Kw is 16 or greater (maximum Kw is 18.6) at a driving current of 1 μA. The cross-point device serves to reduce a leakage current without a diode. Describing in greater detail, the left part of FIG. 7 shows a case in which Al₂O₃ and Ta₂O₅ are applied. Here, the changed incline of dotted lines indicates the improved nonlinearity characteristic of the Ta₂O₅ tunnel barrier. The right part of FIG. 7 shows that the switching characteristic of Ta₂O₅ is not changed when the structure is changed, unlike the TiO₂ tunnel barrier. This confirms that Ta₂O₅ can sufficiently serve as a tunnel barrier. The lower part of FIG. 7 shows that a Kw value with respect to a dynamic current value and an on/off ratio value is higher than that of the other tunnel barriers. This confirms that the nonlinearity characteristic is superior and the leakage current is reduced. Accordingly, the cross-point ReRAM structure can prevent a leakage current from being formed, which is caused by a half voltage that would occur due to use of a diode which causes a half voltage to be applied in a portion other than a read cell.

Although the present invention has been described in relation to the certain exemplary embodiments, it should be understood that the present invention is not limited thereto. The foregoing embodiments can be made into various alterations and modifications without departing from the scope of the appended Claims, and all such alterations and modifications fall within the scope of the present invention. Therefore, the present invention shall be defined by only the claims and their equivalents.

1. A nonvolatile resistive switching memory (ReRAM) device having no selection device, which ReRAM device comprising:
a lower electrode that is formed on on a substrate;
a metal oxide layer that is formed on the lower electrode, the metal oxide layer having a resistive switching characteristic;
an upper electrode that is formed on the metal oxide layer; and
a tunnel barrier oxide film that is formed between the lower electrode and the metal oxide layer, thereby forming a double oxide film structure, the tunnel barrier oxide film being made of a material, a band energy gap and a conduction band offset of which are lower than those of the metal oxide layer, and which does not cause interface switching.

2. The nonvolatile resistive switching memory (ReRAM) device having no selection device according to claim 1, wherein the tunnel barrier oxide film is formed of a material, the crystallization temperature of which is 500° C. or higher.

3. The nonvolatile resistive switching memory (ReRAM) device having no selection device according to claim 1, wherein the tunnel barrier oxide film is made of one selected from a group consisting of Ta₂O₅, Nb₂O₅, BaTiO₃ and BaZrO₃.

4. The nonvolatile resistive switching memory (ReRAM) device having no selection device according to claim 4, wherein the metal oxide layer is made of one selected from a group consisting of ZrO₂, HfO₂, SiO₂, Al₂O₃, ZrAlOx, HfAlOx, HfSiOx and La₂O.

5. The nonvolatile resistive switching memory (ReRAM) device having no selection device according to claim 1, wherein the resistive switching memory (ReRAM) device is applied to a cross-point ReRAM device structure, thereby reducing a sneak current.

6. A method of fabricating a nonvolatile resistive switching memory (ReRAM) device having no selection device, the method comprising the steps of:
forming a lower electrode on a substrate;
forming a metal oxide layer having a resistive switching characteristic on the lower electrode;
forming an upper electrode on the metal oxide layer; and
forming a tunnel barrier oxide film between the lower electrode and the metal oxide layer, thereby forming a double oxide film structure, the tunnel barrier oxide film being made of a material, a band energy gap and a conduction band offset of which are lower than those of the metal oxide layer, and which does not cause interface switching.

7. The method according to claim 6, wherein the tunnel barrier oxide film is formed of a material, the crystallization temperature of which is 500° C. or higher.

8. The method according to claim 6, wherein the tunnel barrier oxide film is made of one selected from a group consisting of Ta₂O₅, Nb₂O₅, BaTiO₃ and BaZrO₃.

9. The method according to claim 8, wherein the metal oxide layer is made of one selected from a group consisting of ZrO₂, HfO₂, SiO₂, Al₂O₃, ZrAlOx, HfAlOx, HfSiOx and La₂O.
